(19) United States
(12) Patent Application Publication
(10) Pub. No.: US 2025/0073590 A1
(43) Pub. Date: Mar. 6, 2025

(54) AERODYNAMIC FORCE MODEL FOR REAL-TIME DISTRIBUTED PHYSICS SIMULATION

(71) Applicant: Roblox Corporation, San Mateo, CA (US)

(72) Inventors: Milad Rakhsha, San Jose, CA (US); Xiaoting Zhang, San Mateo, CA (US); Maciej Mizerski, Kelowna (CA); Jun Kudo, Oakland, CA (US); Wei-Ting Liao, Seattle, WA (US); Alexander Polyakov, Vancouver (CA); Kyle Khem Chand, Livermore, CA (US); Hsueh-Ti Liu, Burnaby (CA)

(73) Assignee: Roblox Corporation, San Mateo, CA (US)

(21) Appl. No.: 18/818,255

(22) Filed: Aug. 28, 2024

Related U.S. Application Data
(60) Provisional application No. 63/535,009, filed on Aug. 28, 2023.

(51) Int. Cl. A63F 13/57; A63F 13/803; G06T 13/00; G06T 17/20

(52) U.S. Cl. CPC A63F 13/57; G06T 13/00; G06T 17/205; A63F 13/803

(57) ABSTRACT

Some implementations relate to methods, systems and computer readable media to provide an aerodynamic force model for real-time distributed physics simulation. According to one aspect, a computer-implemented method includes receiving a description of a mechanism that includes physically coupled geometric assemblies within a virtual experience, with each geometric assembly defining a surface mesh. The description includes motion data of the mechanism. The method further includes, for each geometric assembly, identifying exposed surface areas of the surface mesh. The method further includes evaluating an aerodynamic force model based on the exposed surface areas and the motion data of the mechanism, where the aerodynamic force model includes a pressure coefficient that varies based on an angle of attack and based on windward and leeward facing surfaces. The method further includes integrating the aerodynamic force models into a physics simulation to refine the motion data of the mechanism.

### CROSS-REFERENCE TO RELATED APPLICATIONS

This application claims priority under 35 U.S.C. § 119(e) to U.S. Provisional Patent Application No. 63/535,009, filed on Aug. 28, 2023, the contents of which are hereby incorporated by reference herein in its entirety.

### TECHNICAL FIELD

Implementations relate generally to the field of physics simulation. More specifically, implementations relate to methods, systems and computer readable media to provide an aerodynamic force model for real-time distributed physics simulation.

### BACKGROUND

Aerodynamic modeling has long been a critical component in the design and simulation of physical objects interacting with air and other gaseous environments, such as in aerospace engineering, automotive design, and environmental simulations. Traditional aerodynamic models typically rely on high-fidelity computational simulations that solve complex equations to capture the detailed behavior of airflows around objects. While these models are highly accurate, they are also computationally demanding and require significant processing time and resources, making them impractical for real-time applications where speed and responsiveness are critical, such as in interactive simulations and video games.

In the realm of real-time simulations, particularly in gaming and virtual experiences, simplified aerodynamic models have been developed to approximate air interactions without the computational burden of full-scale simulations. These models often utilize empirical data or simplified mathematical equations, such as drag models, to estimate forces acting on objects based on their shape, velocity, and orientation. However, these approaches generally assume uniform or simplistic airflow patterns and fail to account for more complex phenomena like turbulence, wake effects, and the interactions between multiple objects. As a result, while these models provide sufficient performance for basic simulations, they lack the accuracy and realism required for more sophisticated applications, such as simulating the behavior of aircraft or other dynamic systems involving complex air interactions.

Previous attempts to improve the accuracy of real-time aerodynamic models have included the use of precomputed lookup tables and interpolation methods, where forces and coefficients are stored for various configurations and retrieved during simulation. While these techniques can enhance performance and allow for some degree of complexity, they are typically constrained by the granularity of the precomputed data and do not adapt well to changes in the object's geometry or environmental conditions in real time. Additionally, such models are often limited to rigid body dynamics and do not integrate with deformable objects or assemblies of multiple interacting parts, further restricting their applicability in diverse virtual experiences. The challenge of balancing computational efficiency with aerodynamic accuracy remains significant, particularly as virtual experiences continue to grow in complexity and demand more sophisticated simulations.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Implementations described herein relate to methods, systems, and computer-readable media for providing an aerodynamic force model for real-time distributed physics simulation.

According to one aspect, a computer-implemented method receives a description of a mechanism including physically coupled geometric assemblies within a virtual experience, with each geometric assembly defining a surface mesh. The description includes motion data of the mechanism. For each geometric assembly, exposed surface areas of the surface mesh are identified, and an aerodynamic force model is evaluated based on the exposed surface areas and the motion data of the mechanism, where the aerodynamic force model includes a pressure coefficient that varies based on an angle of attack and based on windward and leeward facing surfaces. The aerodynamic force models are integrated into a physics simulation to refine the motion data of the mechanism.

In some implementations, the aerodynamic force model includes a pressure model based on pressure on the exposed surface areas of the geometric assemblies in relative motion to air simulated within the virtual experience.

In some implementations, identifying the exposed surface areas of the surface meshes includes utilizing low discrepancy sampling and ray casting.

In some implementations, integrating the aerodynamic force models into the physics simulation includes utilizing an integrator adapted to apply influence of aerodynamic forces of the aerodynamic force model.

In some implementations, evaluating the aerodynamic force model includes utilizing high-order quadrature to approximate a force integral on the exposed surface areas. In some implementations, the high-order quadrature utilizes a predetermined number of quadrature points determined based on a trade-off between accuracy and computational cost.

In some implementations, evaluating the aerodynamic force model includes utilizing a pre-computed spherical harmonic interpolator for the aerodynamic force model. In some implementations, evaluating the aerodynamic force model further includes evaluating derivatives of the aerodynamic force model with respect to linear and angular velocity unit vectors directly from the pre-computed spherical harmonic interpolator.

In some implementations, evaluating the aerodynamic force model includes determining that the evaluation is being performed with respect to the surface mesh defined by the geometry assembly that is above a specified threshold; and generating a set of optimized quadrature points and weights for the surface mesh using an optimization process. In some implementations, the set of optimized quadrature points and weights is used for real-time force evaluation on the surface mesh.

In some implementations, evaluating the aerodynamic force model includes utilizing a mesh simplification technique to reduce a number of triangles in the surface mesh defined by the geometric assembly prior to occlusion detection and exposed surface area calculation.

In some implementations, evaluating the aerodynamic force model includes pre-computing coefficients for Ft and Fc terms of the force model during a geometric assembly pre-processing stage.

According to another aspect, a system includes one or more processors and memory coupled to the one or more processors storing instructions that, when executed by the one or more processors, cause the system to perform operations including: receiving a description of a mechanism including physically coupled geometric assemblies within a virtual experience, with each geometric assembly defining a surface mesh. The description further includes motion data of the mechanism. For each geometric assembly, exposed surface areas of the surface mesh are identified, and an aerodynamic force model is evaluated based on the exposed surface areas and the motion data of the mechanism, where the aerodynamic force model includes a pressure coefficient that varies based on an angle of attack and based on windward and leeward facing surfaces. The aerodynamic force models are integrated into a physics simulation to refine the motion data of the mechanism.

In some implementations, integrating the aerodynamic force models into the physics simulation includes utilizing an integrator that is an explicit integrator with adaptive time steps based on the magnitude of the evaluated aerodynamic forces.

In some implementations, integrating the aerodynamic force models into the real-time physics simulation includes utilizing an integrator that is an implicit integrator formulated to mitigate one or more non-linearities introduced by the aerodynamic force model.

In some implementations, evaluating the aerodynamic force model includes identifying non-exposed surface areas of the surface meshes, and excluding the non-exposed surface areas of the surface meshes from the exposed surface area calculation.

In some implementations, evaluating the aerodynamic force model includes utilizing turbulence modeling to model random fluctuations in the aerodynamic forces acting on the mechanism.

In some implementations, evaluating the aerodynamic force model includes utilizing a table lookup for the pressure coefficient within the force model, wherein a table stores pre-computed pressure coefficient values for a range of angles of attack and incorporates interpolation for intermediate values.

In some implementations, evaluating the aerodynamic force model includes utilizing a machine learning model pre-trained on real-world aerodynamic data to predict at least the pressure coefficient for a given angle of attack.

In some implementations, the real-time physics simulation is a physics simulation engine within a video game, and the mechanism represents an object or character within a virtual space of the video game.

According to another aspect, a non-transitory computer readable medium with instructions stored thereon is provided that, when executed by a processor, cause the processor to perform operations. The operations include: receiving a description of a mechanism including physically coupled geometric assemblies within a virtual experience, with each geometric assembly defining a surface mesh. The description further includes motion data of the mechanism. For each geometric assembly, exposed surface areas of the surface mesh are identified, and an aerodynamic force model is evaluated based on the exposed surface areas and the motion data of the mechanism, where the aerodynamic force model includes a pressure coefficient that varies based on an angle of attack and based on windward and leeward facing surfaces. The aerodynamic force models are integrated into a physics simulation to refine the motion data of the mechanism.

According to yet another aspect, portions, features, and implementation details of the systems, methods, and non-transitory computer-readable media may be combined to form additional aspects, including some aspects which omit and/or modify some or portions of individual components or features, include additional components or features, and/or other modifications, and all such modifications are within the scope of this disclosure.

### BRIEF DESCRIPTION OF DRAWINGS

FIG. 1 is a diagram of an example system architecture to provide an aerodynamic force model for real-time distributed physics simulation, in accordance with some implementations.

FIG. 2 is a flow diagram illustrating a method to provide an aerodynamic force model for real-time distributed physics simulation, in accordance with some implementations.

FIG. 3 is a diagram illustrating an example implementation of a triangle occlusion algorithm on an aircraft mesh, in accordance with some implementations.

FIG. 4 is a diagram illustrating an example of an aerodynamic force evaluation on each triangle in a mesh, in accordance with some implementations.

FIG. 5 is a diagram illustrating an example of an aerodynamic force evaluation, in accordance with some implementations.

FIG. 6 is a diagram illustrating an example of mechanisms that are decomposed into assemblies whose geometry is fixed, in accordance with some implementations.

FIG. 7 is a block diagram that illustrates an example computing device, in accordance with some implementations.

### DETAILED DESCRIPTION

In the following detailed description, reference is made to the accompanying drawings, which form a part hereof. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented herein. Aspects of the present disclosure, as generally described herein, and illustrated in the Figures, can be arranged, substituted, combined, separated, and designed in a wide variety of different configurations, all of which are contemplated herein.

References in the specification to “some implementations”, “an implementation”, “an example implementation”, etc. indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, such feature, structure, or characteristic may be effected in connection with other implementations whether or not explicitly described.

Some technical advantages of one or more described features include the ability to accurately simulate aerodynamic forces on complex mechanisms in real-time (e.g., with less than a threshold latency that enables simulations to be performed for a game or virtual experience that a user participates in), even when these mechanisms are composed of multiple moving parts. The decomposition of a mechanism into static assemblies with meshes coupled to each other allows for in-depth aerodynamic analysis while maintaining computational efficiency. By applying aerodynamic force models independently to each assembly and then aggregating the forces a scalable approach is provided to simulate interactions between multiple bodies within a single mechanism. This feature is particularly advantageous in applications such as, e.g., flight simulation, where precise modeling of aerodynamic forces is important for realistic behavior.

Another technical advantage of some implementations is the integration of a high-performance spherical harmonic interpolator, which enables constant-time evaluations of aerodynamic forces, torques, and Jacobian matrices regardless of the complexity of the geometry. This interpolator is optimized to use significantly less memory compared to traditional techniques, such as cube-map techniques, making it suitable for use on low-end devices or in environments where memory resources are limited. The ability to maintain low memory usage while delivering consistent performance ensures that the simulation can model a large number of aerodynamic bodies simultaneously, without compromising the accuracy or responsiveness of the simulation.

Another technical advantage in some implementations is the use of a semi-implicit velocity integration method, which enhances the stability and robustness of the simulation, particularly when dealing with highly nonlinear aerodynamic forces. These implementations automatically switch between explicit and implicit integration techniques based on the dynamics of the system, allowing for accurate modeling of both constrained and unconstrained motion within the mechanism. The ability to dynamically adapt the integration method to the specific conditions of the simulation reduces the risk of numerical instability, particularly in scenarios involving high relative velocities and complex aerodynamic interactions.

Another technical advantage in some implementations is the asynchronous processing of geometry and force models, which enables maintaining real-time performance even in distributed simulations. This orchestration of asynchronous tasks ensures that dynamic changes can be modeled in the simulation environment, such as modifications to the geometry or updates to the force models, without introducing latency or performance bottlenecks. By distributing the computational load across multiple processes, complex simulations involving numerous interacting aerodynamic bodies can be performed efficiently, which is well-suited for large-scale or distributed simulation environments.

### System Architecture

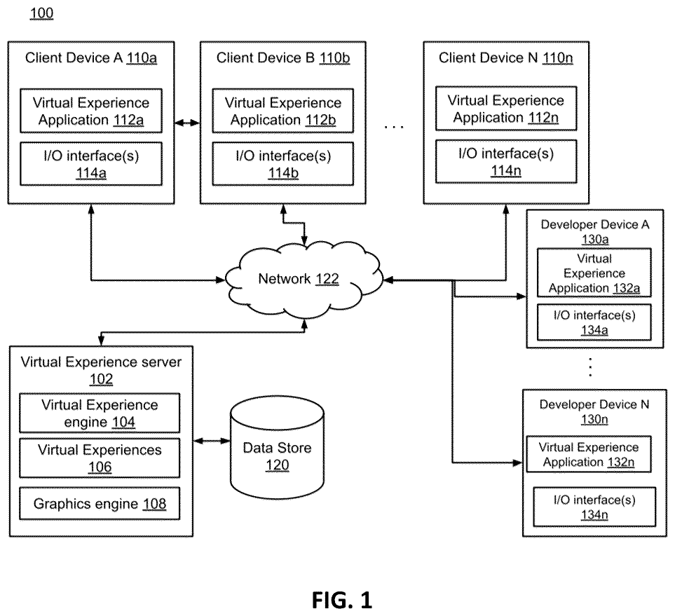

FIG. 1 is a diagram of an example system architecture that can be used to provide mesh retopology for improved animation of three-dimensional avatar heads, in accordance with some implementations. FIG. 1 and the other figures use like reference numerals to identify similar elements. A letter after a reference numeral, such as “110,” indicates that the text refers specifically to the element having that particular reference numeral. A reference numeral in the text without a following letter, such as “110,” refers to any or all of the elements in the figures bearing that reference numeral (e.g. “110” in the text refers to reference numerals “110a,” “110b,” and/or “110n” in the figures).

The system architecture 100 (also referred to as “system” herein) includes online virtual experience server 102, data store 120, client devices 110a, 110b, and 110n (generally referred to as “client device(s) 110” herein), and developer devices 130a and 130n (generally referred to as “developer device(s) 130” herein). Virtual experience server 102, data store 120, client devices 110, and developer devices 130 are coupled via network 122. In some implementations, client devices(s) 110 and developer device(s) 130 may refer to the same or same type of device.

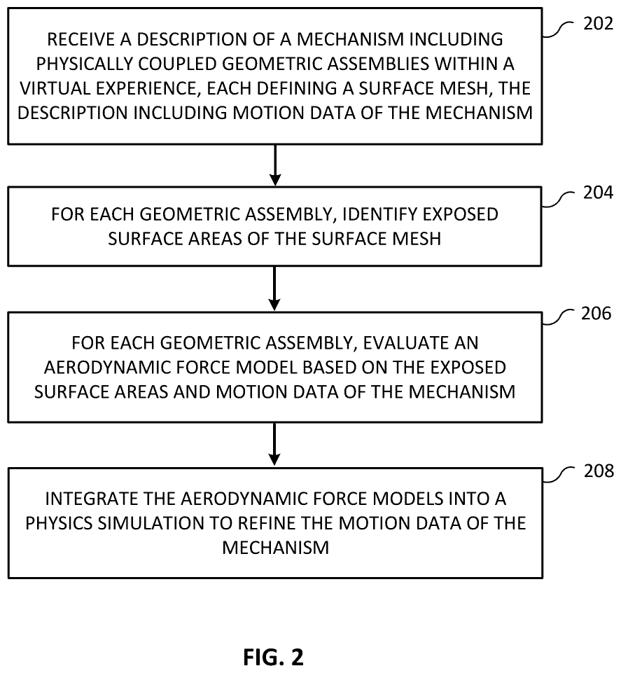

Online virtual experience server 102 can include, among other things, a virtual experience engine 104, one or more virtual experiences 106, and graphics engine 108. In some implementations, the graphics engine 108 may be a system, application, or module that permits the online virtual experience server 102 to provide graphics and animation capability. In some implementations, the graphics engine 108 may perform one or more of the operations described below in connection with the flowchart shown in FIG. 2. In one or more additional or alternative implementations, the operations described below may be performed on one or more client devices 110, or one or more developer devices 130. In some implementations, where the operations are performed depends at least in part on computational resources, e.g., memory, processing power, or disk space. A client device 110 can include a virtual experience application 112, and input/output (I/O) interfaces 114 (e.g., input/output devices). The input/output devices can include one or more of a microphone, speakers, headphones, display device, mouse, keyboard, game controller, touchscreen, virtual reality consoles, etc.

A developer device 130 can include a virtual experience application 132, and input/output (I/O) interfaces 134 (e.g., input/output devices). The input/output devices can include one or more of a microphone, speakers, headphones, display device, mouse, keyboard, game controller, touchscreen, virtual reality consoles, etc.

System architecture 100 is provided for illustration. In different implementations, the system architecture 100 may include the same, fewer, more, or different elements configured in the same or different manner as that shown in FIG. 1.

In some implementations, network 122 may include a public network (e.g., the Internet), a private network (e.g., a local area network (LAN) or wide area network (WAN)), a wired network (e.g., Ethernet network), a wireless network (e.g., an 802.11 network, a Wi-Fi® network, or wireless LAN (WLAN)), a cellular network (e.g., a 5G network, a Long Term Evolution (LTE) network, etc.), routers, hubs, switches, server computers, or a combination thereof.

In some implementations, the data store 120 may be a non-transitory computer readable memory (e.g., random access memory), a cache, a drive (e.g., a hard drive), a flash drive, a database system, or another type of component or device capable of storing data. The data store 120 may also include multiple storage components (e.g., multiple drives or multiple databases) that may also span multiple computing devices (e.g., multiple server computers). In some implementations, data store 120 may include cloud-based storage.

In some implementations, the online virtual experience server 102 can include a server having one or more computing devices (e.g., a cloud computing system, a rackmount server, a server computer, cluster of physical servers, etc.). In some implementations, the online virtual experience server 102 may be an independent system, may include multiple servers, or be part of another system or server.

In some implementations, the online virtual experience server 102 may include one or more computing devices (such as a rackmount server, a router computer, a server computer, a personal computer, a mainframe computer, a laptop computer, a tablet computer, a desktop computer, etc.), data stores (e.g., hard disks, memories, databases), networks, software components, and/or hardware components that may be used to perform operations on the online virtual experience server 102 and to provide a user with access to online virtual experience server 102. The online virtual experience server 102 may also include a website (e.g., a web page) or application back-end software that may be used to provide a user with access to content provided by online virtual experience server 102. For example, users may access online virtual experience server 102 using the virtual experience application 112 on client devices 110.

In some implementations, virtual experience session data are generated via online virtual experience server 102, virtual experience application 112, and/or virtual experience application 132, and are stored in data store 120. With permission from virtual experience participants, virtual experience session data may include associated metadata, e.g., virtual experience identifier(s); device data associated with the participant(s); demographic information of the participant(s); virtual experience session identifier(s); chat transcripts; session start time, session end time, and session duration for each participant; relative locations of participant avatar(s) within a virtual experience environment; purchase(s) within the virtual experience by one or more participants(s); accessories utilized by participants; etc.

In some implementations, online virtual experience server 102 may be a type of social network providing connections between users or a type of user-generated content system that allows users (e.g., end-users or consumers) to communicate with other users on the online virtual experience server 102, where the communication may include voice chat (e.g., synchronous and/or asynchronous voice communication), video chat (e.g., synchronous and/or asynchronous video communication), or text chat (e.g., 1:1 and/or N:N synchronous and/or asynchronous text-based communication). A record of some or all user communications may be stored in data store 120 or within virtual experiences 106. The data store 120 may be utilized to store chat transcripts (text, audio, images, etc.) exchanged between participants.

In some implementations of the disclosure, a “user” may be represented as a single individual. However, other implementations of the disclosure encompass a “user” (e.g., creating user) being an entity controlled by a set of users or an automated source. For example, a set of individual users federated as a community or group in a user-generated content system may be considered a “user.”

In some implementations, online virtual experience server 102 may be or include a virtual gaming server. For example, the gaming server may provide single-player or multiplayer games to a community of users that may access a “system” herein that includes online gaming server 102, data store 120, and client device 110 and/or may interact with virtual experiences using client devices 110 via network 122. In some implementations, virtual experiences (including virtual realms or worlds, virtual games, other computer-simulated environments) may be two-dimensional (2D) virtual experiences, three-dimensional (3D) virtual experiences (e.g., 3D user-generated virtual experiences), virtual reality (VR) experiences, or augmented reality (AR) experiences, for example. In some implementations, users may participate in interactions (such as gameplay) with other users. In some implementations, a virtual experience may be experienced in real-time with other users of the virtual experience.

In some implementations, virtual experience engagement may refer to the interaction of one or more participants using client devices (e.g., 110) within a virtual experience (e.g., 106) or the presentation of the interaction on a display or other output device (e.g., 114) of a client device 110. For example, virtual experience engagement may include interactions with one or more participants within a virtual experience or the presentation of the interactions on a display of a client device.

In some implementations, a virtual experience 106 can include an electronic file that can be executed or loaded using software, firmware or hardware configured to present the virtual experience content (e.g., digital media item) to an entity. In some implementations, a virtual experience application 112 may be executed and a virtual experience 106 rendered in connection with a virtual experience engine 104. In some implementations, a virtual experience 106 may have a common set of rules or common goal, and the environment of a virtual experience 106 shares the common set of rules or common goal. In some implementations, different virtual experiences may have different rules or goals from one another.

In some implementations, virtual experiences may have one or more environments (also referred to as “virtual experience environments”, “virtual environments”, or “virtual spaces” herein) where multiple environments may be linked. An example of a virtual environment may be a three-dimensional (3D) environment. The one or more environments of a virtual experience 106 may be collectively referred to as a “world” or “virtual experience world” or “gaming world” or “virtual world” or “virtual space” or “universe” herein. An example of a world may be a 3D world of a virtual experience 106. For example, a user may build a virtual environment that is linked to another virtual environment created by another user. A character (avatar) of the virtual experience may cross the virtual border to enter the adjacent virtual environment.

It may be noted that 3D environments or 3D worlds use graphics that use a three-dimensional representation of geometric data representative of virtual experience content (or at least present virtual experience content to appear as 3D content whether or not 3D representation of geometric data is used). 2D environments or 2D worlds use graphics that use two-dimensional representation of geometric data representative of virtual experience content.

In some implementations, the online virtual experience server 102 can host one or more virtual experiences 106 and can permit users to interact with the virtual experiences 106 using a virtual experience application 112 of client devices 110. Users of the online virtual experience server 102 may play, create, interact with, or build virtual experiences 106, communicate with other users, and/or create and build objects (e.g., also referred to as “item(s)” or “virtual experience objects” or “virtual experience item(s)” herein) of virtual experiences 106.

For example, in generating user-generated virtual items, users may create characters (avatars), decoration for the characters, one or more virtual environments for an interactive virtual experience, or build structures used in a virtual experience 106, among others. In some implementations, users may buy, sell, or trade virtual experience objects, such as in-platform currency (e.g., virtual currency), with other users of the online virtual experience server 102. In some implementations, online virtual experience server 102 may transmit virtual experience content to virtual experience applications (e.g., 112). In some implementations, virtual experience content (also referred to as “content” herein) may refer to any data or software instructions (e.g., virtual experience objects, virtual experience, user information, video, images, commands, media item, etc.) associated with online virtual experience server 102 or virtual experience applications. In some implementations, virtual experience objects (e.g., also referred to as “item(s)” or “objects” or “virtual objects” or “virtual experience item(s)” herein) may refer to objects that are used, created, shared or otherwise depicted in virtual experience applications 106 of the online virtual experience server 102 or virtual experience applications 112 of the client devices 110. For example, virtual experience objects may include a part, model, character, accessories, tools, weapons, clothing, buildings, vehicles, currency, flora, fauna, components of the aforementioned (e.g., windows of a building), and so forth.

It may be noted that the online virtual experience server 102 hosting virtual experiences 106, is provided for purposes of illustration. In some implementations, online virtual experience server 102 may host one or more media items that can include communication messages from one user to one or more other users. With user permission and express user consent, the online virtual experience server 102 may analyze chat transcripts data to improve the virtual experience platform. Media items can include, but are not limited to, digital video, digital movies, digital photos, digital music, audio content, melodies, website content, social media updates, electronic books, electronic magazines, digital newspapers, digital audio books, electronic journals, web blogs, real simple syndication (RSS) feeds, electronic comic books, software applications, etc. In some implementations, a media item may be an electronic file that can be executed or loaded using software, firmware or hardware configured to present the digital media item to an entity.

In some implementations, a virtual experience 106 may be associated with a particular user or a particular group of users (e.g., a private virtual experience), or made widely available to users with access to the online virtual experience server 102 (e.g., a public virtual experience). In some implementations, where online virtual experience server 102 associates one or more virtual experiences 106 with a specific user or group of users, online virtual experience server 102 may associate the specific user(s) with a virtual experience 106 using user account information (e.g., a user account identifier such as username and password).

In some implementations, online virtual experience server 102 or client devices 110 may include a virtual experience engine 104 or virtual experience application 112. In some implementations, virtual experience engine 104 may be used for the development or execution of virtual experiences 106. For example, virtual experience engine 104 may include a rendering engine (“renderer”) for 2D, 3D, VR, or AR graphics, a physics engine, a collision detection engine (and collision response), sound engine, scripting functionality, animation engine, artificial intelligence engine, networking functionality, streaming functionality, memory management functionality, threading functionality, scene graph functionality, or video support for cinematics, among other features. The components of the virtual experience engine 104 may generate commands that help compute and render the virtual experience (e.g., rendering commands, collision commands, physics commands, etc.) In some implementations, virtual experience applications 112 of client devices 110, respectively, may work independently, in collaboration with virtual experience engine 104 of online virtual experience server 102, or a combination of both.

In some implementations, both the online virtual experience server 102 and client devices 110 may execute a virtual experience engine (104 and 112, respectively). The online virtual experience server 102 using virtual experience engine 104 may perform some or all the virtual experience engine functions (e.g., generate physics commands, rendering commands, etc.), or offload some or all the virtual experience engine functions to virtual experience engine 104 of client device 110. In some implementations, each virtual experience 106 may have a different ratio between the virtual experience engine functions that are performed on the online virtual experience server 102 and the virtual experience engine functions that are performed on the client devices 110. For example, the virtual experience engine 104 of the online virtual experience server 102 may be used to generate physics commands in cases where there is a collision between at least two virtual experience objects, while the additional virtual experience engine functionality (e.g., generate rendering commands) may be offloaded to the client device 110. In some implementations, the ratio of virtual experience engine functions performed on the online virtual experience server 102 and client device 110 may be changed (e.g., dynamically) based on virtual experience engagement conditions. For example, if the number of users engaging in a particular virtual experience 106 exceeds a threshold number, the online virtual experience server 102 may perform one or more virtual experience engine functions that were previously performed by the client devices 110.

For example, users may be playing a virtual experience 106 on client devices 110, and may send control instructions (e.g., user inputs, such as right, left, up, down, user election, or character position and velocity information, etc.) to the online virtual experience server 102. Subsequent to receiving control instructions from the client devices 110, the online virtual experience server 102 may send experience instructions (e.g., position and velocity information of the characters participating in the group experience or commands, such as rendering commands, collision commands, etc.) to the client devices 110 based on control instructions. For instance, the online virtual experience server 102 may perform one or more logical operations (e.g., using virtual experience engine 104) on the control instructions to generate experience instruction(s) for the client devices 110. In other instances, online virtual experience server 102 may pass one or more or the control instructions from one client device 110 to other client devices (e.g., from client device 110a to client device 110b) participating in the virtual experience 106. The client devices 110 may use the experience instructions and render the virtual experience for presentation on the displays of client devices 110.

In some implementations, the control instructions may refer to instructions that are indicative of actions of a user's character (avatar) within the virtual experience. For example, control instructions may include user input to control action within the experience, such as right, left, up, down, user selection, gyroscope position and orientation data, force sensor data, etc. The control instructions may include character position and velocity information. In some implementations, the control instructions are sent directly to the online virtual experience server 102. In other implementations, the control instructions may be sent from a client device 110 to another client device (e.g., from client device 110b to client device 110n), where the other client device generates experience instructions using the local virtual experience engine 104. The control instructions may include instructions to play a voice communication message or other sounds from another user on an audio device (e.g., speakers, headphones, etc.), for example voice communications or other sounds generated using the audio spatialization techniques as described herein.

In some implementations, experience instructions may refer to instructions that enable a client device 110 to render a virtual experience, such as a multiparticipant virtual experience. The experience instructions may include one or more of user input (e.g., control instructions), character position and velocity information, or commands (e.g., physics commands, rendering commands, collision commands, etc.).

In some implementations, characters (or virtual experience objects generally) are constructed from components, one or more of which may be selected by the user, that automatically join together to aid the user in editing.

In some implementations, a character is implemented as a 3D model and includes a surface representation used to draw the character (also known as a skin or mesh) and a hierarchical set of interconnected bones (also known as a skeleton or rig). The rig may be utilized to animate the character and to simulate motion and action by the character. The 3D model may be represented as a data structure, and one or more parameters of the data structure may be modified to change various properties of the character, e.g., dimensions (height, width, girth, etc.); body type; movement style; number/type of body parts; proportion (e.g., shoulder and hip ratio); head size; etc.

One or more characters (also referred to as an “avatar” or “model” herein) may be associated with a user where the user may control the character to facilitate a user's interaction with the virtual experience 106.

In some implementations, a character may include components such as body parts (e.g., hair, arms, legs, etc.) and accessories (e.g., t-shirt, glasses, decorative images, tools, etc.). In some implementations, body parts of characters that are customizable include head type, body part types (arms, legs, torso, and hands), face types, hair types, and skin types, among others. In some implementations, the accessories that are customizable include clothing (e.g., shirts, pants, hats, shoes, glasses, etc.), weapons, or other tools.

In some implementations, for some asset types, e.g., shirts, pants, etc. the online virtual experience platform may provide users access to simplified 3D virtual object models that are represented by a mesh of a low polygon count, e.g., between about 20 and about 30 polygons.

In some implementations, the user may also control the scale (e.g., height, width, or depth) of a character or the scale of components of a character. In some implementations, the user may control the proportions of a character (e.g., blocky, anatomical, etc.). It may be noted that is some implementations, a character may not include a character virtual experience object (e.g., body parts, etc.) but the user may control the character (without the character virtual experience object) to facilitate the user's interaction with the virtual experience (e.g., a puzzle game where there is no rendered character game object, but the user still controls a character to control in-game action).

In some implementations, a component, such as a body part, may be a primitive geometrical shape such as a block, a cylinder, a sphere, etc., or some other primitive shape such as a wedge, a torus, a tube, a channel, etc. In some implementations, a creator module may publish a user's character for view or use by other users of the online virtual experience server 102. In some implementations, creating, modifying, or customizing characters, other virtual experience objects, virtual experiences 106, or virtual experience environments may be performed by a user using a I/O interface (e.g., developer interface) and with or without scripting (or with or without an application programming interface (API)). It may be noted that for purposes of illustration, characters are described as having a humanoid form. It may further be noted that characters may have any form such as a vehicle, animal, animate or inanimate object, or other creative form.

In some implementations, the online virtual experience server 102 may store characters created by users in the data store 120. In some implementations, the online virtual experience server 102 maintains a character catalog and virtual experience catalog that may be presented to users. In some implementations, the virtual experience catalog includes images of virtual experiences stored on the online virtual experience server 102. In addition, a user may select a character (e.g., a character created by the user or other user) from the character catalog to participate in the chosen virtual experience. The character catalog includes images of characters stored on the online virtual experience server 102. In some implementations, one or more of the characters in the character catalog may have been created or customized by the user. In some implementations, the chosen character may have character settings defining one or more of the components of the character.

In some implementations, a user's character can include a configuration of components, where the configuration and appearance of components and more generally the appearance of the character may be defined by character settings. In some implementations, the character settings of a user's character may at least in part be chosen by the user. In other implementations, a user may choose a character with default character settings or character setting chosen by other users. For example, a user may choose a default character from a character catalog that has predefined character settings, and the user may further customize the default character by changing some of the character settings (e.g., adding a shirt with a customized logo). The character settings may be associated with a particular character by the online virtual experience server 102.

In some implementations, the client device(s) 110 may each include computing devices such as personal computers (PCs), mobile devices (e.g., laptops, mobile phones, smart phones, tablet computers, or netbook computers), network-connected televisions, gaming consoles, etc. In some implementations, a client device 110 may also be referred to as a “user device.” In some implementations, one or more client devices 110 may connect to the online virtual experience server 102 at any given moment. It may be noted that the number of client devices 110 is provided as illustration. In some implementations, any number of client devices 110 may be used.

In some implementations, each client device 110 may include an instance of the virtual experience application 112, respectively. In one implementation, the virtual experience application 112 may permit users to use and interact with online virtual experience server 102, such as control a virtual character in a virtual experience hosted by online virtual experience server 102, or view or upload content, such as virtual experiences 106, images, video items, web pages, documents, and so forth. In one example, the virtual experience application may be a web application (e.g., an application that operates in conjunction with a web browser) that can access, retrieve, present, or navigate content (e.g., virtual character in a virtual experience, etc.) served by a web server. In another example, the virtual experience application may be a native application (e.g., a mobile application, app, virtual experience program, or a gaming program) that is installed and executes local to client device 110 and allows users to interact with online virtual experience server 102. The virtual experience application may render, display, or present the content (e.g., a web page, a media viewer) to a user. In an implementation, the virtual experience application may also include an embedded media player (e.g., a Flash® or HTML5 player) that is embedded in a web page.

According to aspects of the disclosure, the virtual experience application may be an online virtual experience server application for users to build, create, edit, upload content to the online virtual experience server 102 as well as interact with online virtual experience server 102 (e.g., engage in virtual experiences 106 hosted by online virtual experience server 102). As such, the virtual experience application may be provided to the client device(s) 110 by the online virtual experience server 102. In another example, the virtual experience application may be an application that is downloaded from a server.

In some implementations, each developer device 130 may include an instance of the virtual experience application 132, respectively. In one implementation, the virtual experience application 132 may permit a developer user(s) to use and interact with online virtual experience server 102, such as control a virtual character in a virtual experience hosted by online virtual experience server 102, or view or upload content, such as virtual experiences 106, images, video items, web pages, documents, and so forth. In one example, the virtual experience application may be a web application (e.g., an application that operates in conjunction with a web browser) that can access, retrieve, present, or navigate content (e.g., virtual character in a virtual experience, etc.) served by a web server. In another example, the virtual experience application may be a native application (e.g., a mobile application, app, virtual experience program, or a gaming program) that is installed and executes local to client device 130 and allows users to interact with online virtual experience server 102. The virtual experience application may render, display, or present the content (e.g., a web page, a media viewer) to a user. In an implementation, the virtual experience application may also include an embedded media player (e.g., a Flash® or HTML5 player) that is embedded in a web page.

According to aspects of the disclosure, the virtual experience application 132 may be an online virtual experience server application for users to build, create, edit, upload content to the online virtual experience server 102 as well as interact with online virtual experience server 102 (e.g., provide and/or engage in virtual experiences 106 hosted by online virtual experience server 102). As such, the virtual experience application may be provided to the client device(s) 130 by the online virtual experience server 102. In another example, the virtual experience application 132 may be an application that is downloaded from a server. Virtual experience application 132 may be configured to interact with online virtual experience server 102 and obtain access to user credentials, user currency, etc. for one or more virtual experiences 106 developed, hosted, or provided by a virtual experience developer.

In some implementations, a user may login to online virtual experience server 102 via the virtual experience application. The user may access a user account by providing user account information (e.g., username and password) where the user account is associated with one or more characters available to participate in one or more virtual experiences 106 of online virtual experience server 102. In some implementations, with appropriate credentials, a virtual experience developer may obtain access to virtual experience virtual objects, such as in-platform currency (e.g., virtual currency), avatars, special powers, accessories, which are owned by or associated with other users.

In general, functions described in one implementation as being performed by the online virtual experience server 102 can also be performed by the client device(s) 110, or a server, in other implementations if appropriate. In addition, the functionality attributed to a particular component can be performed by different or multiple components operating together. The online virtual experience server 102 can also be accessed as a service provided to other systems or devices through suitable application programming interfaces (hereinafter “APIs”), and thus is not limited to use in websites.

### Providing an Aerodynamic Force Model

FIG. 2 is a flow diagram illustrating an example method 200 to provide an aerodynamic force model for real-time distributed physics simulation, in accordance with some implementations. In various implementations, the blocks shown in FIG. 2 and described below may be performed by any of the elements illustrated in FIG. 1, e.g., one or more of client devices 110 and/or virtual experience server 102. For example, in a distributed simulation, two or more client devices 100 may perform method 200, or at least one client device 110 and virtual experience server 102 may perform method 200. In some implementations, certain blocks of method 200 may be performed by a client device 110 and other blocks of method 200 may be performed by a virtual experience server 102. Method 200 begins at block 202.

At block 202, a description of a mechanism is received. The term “mechanism” as used herein refers to a collection of interconnected parts or components that operate together within a virtual experience. This mechanism may represent various physical objects, such as, for example, vehicles, machinery, or animated characters within a simulated world. The structure and configuration of the mechanism may be in the form of discrete geometric assemblies, each geometric assembly corresponding to a respective subunit of the mechanism. These geometric assemblies are physically coupled, meaning they are connected in a manner that allows for relative movement or interaction, and are governed by the constraints and rules defined within a simulation of the mechanism in the virtual experience. Simulation refers to motion of one or more parts of the mechanism in response to forces acting on the mechanism (e.g., wind, water flow, impact with another mechanism, etc.) The simulation may include, for example, motion involving translation (movement along a linear axis), rotating about an axis, or physical deformation (e.g., bending, collapsing, compressing or expanding, etc.)

Each geometric assembly within the mechanism defines a surface mesh. A surface mesh is a digital representation of the outer surface of an assembly, and comprises a network of vertices connected by edges. The surface mesh may have one or more faces. In some implementations, the faces are triangular, forming a mesh that captures the shape and contours of an exterior of the assembly. For example, in a simulation of an aircraft, the mechanism for the aircraft may include geometric assemblies corresponding to components such as the fuselage, wings, and tail, each represented by a respective surface mesh. These surface meshes are used for subsequent computational processes. The surface meshes provide a framework to determine the areas of the assembly that are exposed (i.e., can be acted upon by external forces) and to evaluate the aerodynamic forces that act on the assembly within a virtual space (three-dimensional space in which the mechanism is placed within a virtual experience).

A virtual experience as used herein refers to the simulated environment in which the mechanism is present and operates (e.g., undergoes motion). In various implementations, the simulated environment is generated by a physics engine that models the interactions between objects, including, e.g., their movement, collisions, and responses to various forces like gravity and aerodynamics. In various implementations, a virtual experience can include different types of experiences, such as, for example, video games, meeting rooms, training simulations, virtual prototyping spaces, etc.

In some implementations, a mechanism is associated with a description. The description of a mechanism includes motion data of the mechanism. Motion data includes information related to the movement and orientation of the geometric assemblies of the mechanism over time. In some implementations, motion data includes translational velocities, which describe the rate and direction of movement along a straight path, and rotational velocities, which describe the rate of rotation about an axis. In some implementations, the motion data includes additional kinematic variables such as accelerations. For example, in the context of a flight simulation, motion data might provide information about an aircraft's speed, the direction of its forward movement, the angular velocity of its roll or pitch, and how these variables change over time.

The motion data is combined with the geometric assemblies and their corresponding surface meshes to enable dynamic simulation of the mechanism within the virtual experience. The motion data allows application of aerodynamic force models to the assemblies as the assemblies move, influencing their behavior in a manner consistent with the physical laws being simulated. For example, as a simulated aircraft moves through the virtual space, the motion data is used to calculate the effect of aerodynamic forces such as lift and drag acting on the wings and fuselage. These forces, derived from the aerodynamic force models, affect the aircraft's trajectory and orientation in the simulation. Block 202 is followed by block 204.

At block 204, for each geometric assembly, exposed surface areas of the surface mesh are identified. In some implementations, this identification includes analyzing the surface mesh, which is a digital representation composed of vertices, edges, and triangular faces that collectively define the outer surface of the geometric assembly. The surface mesh is used to determine the areas that are exposed to external forces such as aerodynamic effects.

Exposed surface areas, as used herein, refers to the portions of the surface mesh that are not occluded or hidden by other parts of the mechanism or by other objects within the virtual experience. These exposed areas are the sections of the mesh that can interact with external forces. For example, for a mechanism that corresponds to an aircraft, exposed surface areas might include the leading edges of the wings, the fuselage surfaces, and other parts that are directly facing or are exposed to airflow within the virtual experience (e.g., that may originate from another virtual object, such as another aircraft, natural wind simulated within the virtual experience, etc.). Conversely, areas hidden behind other parts of the mechanism, such as internal components or surfaces shielded by other geometric assemblies, are not considered as exposed.

To identify the exposed surface areas, the surface mesh is analyzed in the context of the mechanism's overall geometry and its positioning within the virtual experience. In some implementations, the process of identifying the exposed surface areas of the surface meshes includes the use of low discrepancy sampling combined with ray casting techniques. These techniques work together to determine the portions of the surface mesh that are exposed to external elements, such as airflow, and the portions that are occluded or hidden by other parts of the mechanism or by other objects within the virtual experience.

In some implementations, low discrepancy sampling can ensure that the surface mesh is analyzed with a distribution of sample points that cover the mesh uniformly. This sampling method generates a set of points that are spread out over different regions of the surface mesh in a manner that avoids clustering, e.g., such that the entire surface area of the mesh is sampled from.

In some implementations, ray casting is used in conjunction with low discrepancy sampling to determine the triangles in the surface mesh that are exposed. In this process, virtual rays are projected from various points in the virtual space of the virtual experience toward the surface mesh. When a ray intersects a triangle on the mesh, it is evaluated if the triangle is directly exposed or if it is occluded by another part of the mechanism or the virtual experience. If the ray reaches the triangle without obstruction, the triangle is marked as exposed. If the ray is blocked before reaching the triangle, the triangle is considered occluded and therefore not exposed.

In some implementations, the identification of exposed surface areas is performed for each geometric assembly independently, taking into account its specific orientation and positioning relative to the other assemblies and objects. This process ensures that even in a complex mechanism with multiple interacting parts, the exposed areas can be determined for each assembly. For example, in a virtual simulation of a vehicle, the exposed surface areas of the hood, doors, roof, and other components can be determined independently, considering how each interacts with external forces like wind or pressure. Block 204 may be followed by block 206.

At block 206, for each geometric assembly, an aerodynamic force model is evaluated based on the exposed surface areas and motion data of the mechanism. The aerodynamic force model includes a pressure coefficient that varies based on an angle of attack and based on windward and leeward facing surfaces. The aerodynamic force model is based on principles of fluid dynamics, where forces such as, e.g., lift, drag, and pressure are computed based on how air interacts with the surfaces of the geometric assembly. In some implementations, the evaluation process begins with the application of the force model to the exposed surface areas identified at block 204.

The aerodynamic force model includes a pressure coefficient, which is a dimensionless number that quantifies the pressure distribution on a surface relative to the freestream pressure in the surrounding air. The pressure coefficient varies depending on the angle of attack, which is the angle between the oncoming airflow and a reference line on the surface of the assembly, such as, for example, a chord line in the case of an airfoil. For example, when an aircraft wing assembly is pitched upward, the angle of attack increases, altering the distribution of pressure across the wing's surfaces. The pressure coefficient is calculated for each triangle in the surface mesh, providing a localized measure of aerodynamic pressure that contributes to the overall forces acting on the assembly.

In some implementations, the aerodynamic force model also accounts for the distinction between windward and leeward facing surfaces of the geometric assembly. The windward surface is the side of the assembly that faces into the oncoming airflow, experiencing higher pressure due to direct impact with the air. In contrast, the leeward surface faces away from the airflow and generally experiences lower pressure, sometimes even negative pressure coefficient if the air accelerates over the surface, as is common with the upper surface of an aircraft wing generating lift. In some implementations, the force model varies the pressure coefficient based on which side of the assembly's surface is windward or leeward, allowing for accurate calculation of forces such as lift on wings or drag on bluff bodies.

In some implementations, during the evaluation, the aerodynamic forces acting on the entire geometric assembly are computed by summing the contributions from each triangle in the exposed surface mesh. The forces are computed using the pressure coefficients, the area of each triangle, and the relative velocity of the assembly as derived from the motion data. For example, in the case of an aircraft wing, the system would evaluate the lift generated by each triangle on the wing's surface, integrating these contributions to determine the total lift force acting on the wing. The same process is applied to calculate drag and other aerodynamic forces, with the results influencing the overall motion and behavior of the mechanism.

In some implementations, the aerodynamic force model is based on an aerodynamic analysis of the pressure distribution on flat plates. For each triangle in the surface mesh, the aerodynamic force is expressed as:

$${F}_{t} = q A C ( \cdot ) {n}_{t}$$

where q represents the dynamic pressure, A is the area of the triangle, and Cₚ is the pressure coefficient. The pressure coefficient Cₚ is determined as a function of the dot product between a unit velocity vector [symbol] and an outward-facing unit normal [symbol] of the triangle. This formulation captures the aerodynamic forces acting on both the windward and leeward surfaces of a lifting body. In some implementations, an average pressure coefficient for the windward and leeward surfaces of a 2D flat plate is computed across a range of angles of attack, for example, from −20 to +20 degrees. This range can be used for capturing the behavior of attached flows, where high lift and low drag are prominent. In some implementations, the pressures on both sides of the plate are calculated at multiple different angles and then averaged, resulting in a comprehensive pressure coefficient curve, which is represented by a cubic spline. In some implementations, this curve is used to evaluate the aerodynamic forces for various orientations of the surface mesh in the simulated environment.

In some implementations, one aerodynamic force model is utilized for bluff bodies, e.g., balls, blocks, or cylinders, and another aerodynamic force model is utilized for lifting surfaces, e.g., wings, plates, or rotors. Both of these aerodynamic force models can be written in the pressure coefficient Cₚ formula described above. The function in the formula is integrated by summing contributions from each triangle in a mesh. For bluff bodies, Cₚ is a simple linear function of the velocity and triangle normal unit vectors. In various implementations, this aerodynamic force model is applicable to such “bluff body” objects as, e.g., balls, blocks, buildings, car bodies, balloons, or chunky debris. For lifting surfaces, a Cₚ model may be a cubic spline interpolant of data. Such a model may be more accurate than the previously mentioned simple linear Cₚ model, particularly for lifting surfaces such as, e.g., wings. In various implementations, this more accurate model is applicable to such “lifting surfaces” as, e.g., wings, rotors, leaves, and sails. In some implementations, an aerodynamic force model is selected based on an aspect ratio of geometry of the object. In some implementations, a user may be permitted to override a default selection of an aerodynamic force model and specify an aerodynamic force model the user wishes to use for a particular geometry of an object.

In some implementations, for real-time dynamics within a virtual experience, integrating over large meshes is too expensive. In such a scenario, different techniques may be utilized for approximating these integrals in constant time. In some implementations, for bluff bodies, an aerodynamic force model can be reduced to a single, high-performance, spherical harmonic interpolator over an angular velocity unit vector of a body. In some implementations, all other terms in this aerodynamic force model can be pre-computed, leading to an approach that is efficient in terms of memory and computational power required. In some implementations, an interpolant is computed in an asynchronous process from original mesh data. The original mesh data is discarded after the spherical harmonic interpolant is constructed. In some implementations that employ an aerodynamic force model for lifting surfaces, a fixed number of surface quadrature points (for example, 50-200 quadrature points, depending on the original mesh size) are computed. A mesh is first downsampled to a reduced number of quadrature points, i.e., centroids. In some implementations, blue noise sampling is used for downsampling. In some implementations, quadrature, i.e., integration weights are computed using an asynchronous optimization process and the original mesh data. In some implementations, the original mesh data is discarded once the reduced number of quadrature points are determined. In various implementations, multi-core hardware may be utilized for construction of a spherical harmonic interpolator or construction of a reduced quadrature set.

In some implementations, a threshold is utilized on original mesh size. In some implementations, an appropriate constant time approximation evaluator, e.g., a spherical harmonic interpolator or reduced quadrature points, is selected when a processed mesh meets a threshold on a number of triangles. For example, meshes above 40 triangles may trigger the use of a constant time evaluator.

In various implementations, a mechanism will use a collection of evaluation techniques specific to constituent assemblies of the mechanism, and each mechanism may use a variety of aerodynamic force models. For example, an aircraft may be composed of a bluff fuselage modeled by a large mesh, which will use a simple Cₚ model and spherical harmonic interpolator, with wings also represented by a large mesh, which will use a lifting surface Cₚ model and reduced quadrature point evaluator. Contral surfaces may include simple shapes with less than 40 triangles each, using direct integration in the mesh with one of the two Cₚ models as appropriate given a geometric shape.

In some implementations, a semi-automated switch is implemented that selects an aerodynamic force model based on the geometry of the rigid body. In some implementations, if the rigid body is a lifting surface based on the geometry—such as, for example, a flat plate with a thickness less than 20% of its other dimensions—a particular aerodynamic force model is applied. For other geometries, a more generalized approach can be used for pressure coefficient calculation. This switch allows an aerodynamic force model to be used selectively, ensuring accurate lift simulations while preserving computational efficiency. In some implementations, a detailed force model may be selectively enabled on specific geometries when a high-fidelity representation is necessary to provide accurate simulation.

In some implementations, the aerodynamic force model includes a pressure model based on pressure on the exposed surface areas of the geometric assemblies in relative motion to air simulated within the virtual experience. In some implementations, this pressure model considers the interaction between the exposed surfaces and the surrounding air within the virtual experience. The pressure on each surface area is determined by the relative motion of the geometric assembly through the simulated air, with variations in pressure influenced by factors such as, e.g., velocity, angle of attack, and the orientation of the surface relative to the airflow.

In some implementations, the pressure distribution across the surface mesh of each geometric assembly is computed. The surface mesh, composed of interconnected triangles, is analyzed to determine the pressure on each individual triangle. In some implementations, this evaluation is based on the relative velocity of the air with respect to the surface, where this relative velocity is calculated as the difference between the velocity of the assembly and that of the surrounding air.

In some implementations, the pressure at each point on the surface is further influenced by the local orientation of the surface normal, which dictates the directness of the impact of the airflow. In some implementations, aerodynamic effects associated with different regions of the geometric assembly are accounted for, differentiating between high-pressure and low-pressure areas. High-pressure zones are found on surfaces facing directly into the airflow (i.e., windward surfaces), while low-pressure zones are present on surfaces where the airflow is smoother (i.e., leeward surfaces). In some implementations, these varying pressures across the entire exposed surface area are combined to calculate the total aerodynamic forces acting on the assembly. These forces contribute to both lift and drag, which are derived from the pressure differences across the surface.

In some implementations, evaluating the aerodynamic force model includes utilizing high-order quadrature to approximate the force integral on the exposed surface areas of the geometric assemblies. High-order quadrature refers to numerical integration methods that use a weighted sum of function evaluations at specific points within the domain of integration to approximate the integral. In some implementations, high-order quadrature is utilized when integrating over meshes in order to compute accurate forces and torques, particularly for rotating bodies, such as helicopter rotors. In some implementations, high-order quadrate is utilized for an aerodynamic force model, whether that aerodynamic force model is being applied to bluff bodies or lifting surfaces.

In some implementations, utilizing the high-order quadrature includes dividing the exposed surface areas into a series of smaller elements. In some implementations, these smaller elements are the triangles that make up the surface mesh. For each of these elements, the force contributions at several points, known as quadrature points, are calculated. These points are selected based on the quadrature rule being applied, which determines both the locations of the points and the weights assigned to the function evaluations at those points.

In some implementations, the evaluation of the aerodynamic force model includes the use of a pre-computed spherical harmonic interpolator. Spherical harmonics are mathematical functions defined on the surface of a sphere, commonly used in various fields to approximate complex functions with angular dependency. In the context of aerodynamic modeling, a spherical harmonic interpolator is employed to approximate the distribution of aerodynamic forces across the surface mesh of a geometric assembly. The interpolator utilizes the pre-computed coefficients of spherical harmonics to estimate the aerodynamic forces in a manner that accounts for variations in both the direction and magnitude of airflow relative to the surface.

In some implementations, pre-computation of spherical harmonic coefficients is performed based on analysis of the aerodynamic forces acting on the surface mesh under various conditions. This pre-computation includes solving aerodynamic equations at a plurality of sample points on the surface of the geometric assembly for a range of possible airflow directions. The results are used to generate the coefficients that define the spherical harmonic functions.

In some implementations, evaluating the aerodynamic force model includes evaluating derivatives of the force model with respect to linear and angular velocity unit vectors directly from the pre-computed spherical harmonic interpolator. In some implementations, evaluating the derivatives utilizes existing pre-computed spherical harmonic coefficients. These coefficients, which represent the aerodynamic force distribution as a function of the orientation of the geometric assembly, are used to derive the partial derivatives of the force model with respect to the velocity components. By taking the derivative of the spherical harmonic functions with respect to the unit vectors of linear and angular velocity, the changes to the aerodynamic forces that occur as the assembly's velocity vector changes direction or magnitude can be calculated.

The calculation of these derivatives is performed using the mathematical properties of spherical harmonics, which allow for the efficient computation of derivatives directly from the pre-computed coefficients. This approach avoids the need for additional computationally expensive numerical differentiation during the simulation, thereby preserving the computational performance benefits of the spherical harmonic interpolator. The derivatives provide information for updating the motion data of the mechanism within the simulation, particularly in scenarios where the aerodynamic forces are sensitive to changes in velocity.

In some implementations, the evaluation of the aerodynamic force model includes a conditional process based on the characteristics of the surface mesh. This process includes determining whether the surface mesh in question exceeds a specified threshold, which may relate to, e.g., the mesh's complexity, size, or the number of triangles it contains. This threshold is established to identify surface meshes that require more refined computational techniques to approximate the aerodynamic forces acting on them.

When the surface mesh is identified as meeting the threshold, a reduced set of optimized quadrature points and corresponding weights for the mesh are generated. This generation process involves an optimization process that balances accuracy and computational efficiency in the evaluation of the aerodynamic forces. The optimization process selects specific points on the surface mesh where the force integrals are calculated, in order to minimize the error in the force approximation while also managing the computational resources required. A reduced set of points (for example, 100 points) are computed in order to fix computational cost and use optimization of the corresponding weights and point locations to recover accuracy. Thus, an aerodynamic force model of a large (for example, a 500-triangle) mesh is computed at the same cost as an aerodynamic force model of a smaller (e.g., a 100-triangle) mesh.

The selected quadrature points are those that provide significant contributions to the overall force calculation, given the mesh's complexity and the aerodynamic conditions. In some implementations, the weights associated with these optimized quadrature points are also determined during the optimization process. These weights are used to scale the contributions of each quadrature point when summing the aerodynamic forces across the surface mesh. The optimization process adjusts the weights to ensure that the final force calculation reflects the distribution of forces over the entire surface, even when dealing with complex or highly detailed meshes. In some implementations, the set of optimized quadrature points and weights are used for real-time force evaluation on the surface mesh. Real-time force evaluation refers to the ongoing, dynamic calculation of aerodynamic forces as the simulation progresses, allowing for immediate adjustments to the motion of the mechanism based on the computed forces.

In some implementations, evaluating the aerodynamic force model includes utilizing a mesh simplification technique to reduce the number of triangles in the surface meshes prior to occlusion detection and exposed surface area calculation. Mesh simplification involves reducing the complexity of the surface mesh while preserving its overall shape and features. This reduction is achieved by decreasing the number of triangles that make up the mesh, which in turn reduces the computational load required for subsequent aerodynamic force calculations.

In some implementations, the simplification process includes analyzing the surface mesh to identify areas where the level of detail can be reduced without significantly impacting the accuracy of the aerodynamic force model. In various implementations, the reduction in the level of detail can include merging adjacent triangles, eliminating redundant vertices, or otherwise reducing the geometric complexity of the mesh while maintaining the characteristics that affect aerodynamic behavior. For example, flat or nearly flat regions of the mesh may be simplified aggressively, while areas with sharp edges or significant curvature are preserved with higher detail to capture the aerodynamic forces acting on them.

In some implementations, once the mesh has been simplified, the reduced surface mesh is used for further steps in the aerodynamic force evaluation process, including occlusion detection and exposed surface area calculation. The simplified mesh, with fewer triangles, allows these calculations to be performed more quickly and with less computational overhead. Occlusion detection, which involves determining which parts of the surface mesh are hidden from the airflow by other parts of the mechanism or by other objects, becomes more efficient when performed on a simplified mesh. Similarly, calculating the exposed surface areas, which are the portions of the mesh that directly interact with the airflow, is expedited by working with a less complex mesh.

In some implementations, evaluating the aerodynamic force model includes pre-computing coefficients for Ft and Fc terms of the force model during the geometric assembly pre-processing stage. The terms Ft and Fc refer to specific components of the aerodynamic force model that account for tangential and crossflow forces acting on the surface mesh of the geometric assembly. These forces are influenced by factors such as the relative velocity of the assembly and the orientation of the surface elements within the airflow.

In some implementations, the pre-computation process begins during the pre-processing stage, where the geometric assemblies are analyzed before the simulation is started. During this stage, the coefficients associated with the Ft (i.e., tangential force) and Fc (i.e., crossflow force) components of the aerodynamic force model are calculated. These coefficients are derived based on the geometry of the surface mesh, the range of flow conditions, and the aerodynamic properties of the assembly.

In some implementations, the pre-computed coefficients may be tailored to the specific characteristics of different geometric assemblies, ensuring that the aerodynamic forces are modeled according to the shape and orientation of an assembly that is part of a mechanism within the virtual experience.

In some implementations, evaluating the aerodynamic force model includes identifying non-exposed surface areas of the surface meshes, and excluding the non-exposed surface areas of the surface meshes from the exposed surface area calculation. Non-exposed surface areas are regions of the surface mesh that are not directly subject to external forces such as airflow, often because they are occluded by other parts of the mechanism or by other objects within the virtual experience.

In some implementations, the identification process involves analyzing the geometry and orientation of the surface mesh in relation to the surrounding virtual space and other components of the mechanism. In various implementations, techniques such as, e.g., ray casting or visibility analysis may be utilized to determine which parts of the surface mesh are blocked from the external flow and thus are considered non-exposed. For example, in a complex structure such as a vehicle, parts of the undercarriage might be shielded by the body of the vehicle, rendering those areas non-exposed to the aerodynamic forces generated by the airflow over the vehicle. In some implementations, once the non-exposed surface areas are identified, the system proceeds to exclude these areas from the exposed surface area calculation. This exclusion ensures that only the relevant parts of the surface mesh—those directly interacting with the external forces—are considered in the aerodynamic force model.

In some implementations, evaluating the aerodynamic force model includes utilizing turbulence modeling to model fluctuations (e.g., random fluctuations) in the aerodynamic forces acting on the mechanism. Turbulence refers to the chaotic and irregular variations in airflow that occur in certain fluid dynamic conditions, particularly at high speeds or in the presence of obstacles that disrupt smooth flow.

In some implementations, turbulence modeling includes generating a representation of the fluctuations within the aerodynamic force model. In some implementations, this is done by introducing stochastic elements that simulate the varying pressures and velocities within the airflow as it interacts with the surface mesh of the mechanism. In some implementations mathematical techniques, such as, e.g., random noise generation or spectral methods, are used to produce the fluctuations in a manner that reflects real-world turbulence.

For example, areas of the mechanism that are subject to high-speed flow or abrupt changes in surface geometry may experience greater turbulence, leading to more significant fluctuations in the aerodynamic forces. In some implementations, a turbulence model is used in the aerodynamic force evaluation process to modify the baseline aerodynamic forces calculated from the deterministic components of the model. These deterministic components include forces derived from the surface mesh's shape, orientation, and motion relative to the airflow. In some implementations, the turbulence model superimposes random variations onto these forces.

In some implementations, evaluating the aerodynamic force model includes utilizing a lookup table for the pressure coefficient within the force model, where the lookup table stores pre-computed pressure coefficient values for a range of angles of attack and incorporates interpolation for intermediate values. The pressure coefficient is a dimensionless number that describes the pressure distribution on the surface of a geometric assembly relative to the surrounding air pressure. It varies with the angle of attack, which is the angle between the oncoming airflow and a reference line on the surface, such as the chord line of an airfoil.

In some implementations, pre-computed values of the pressure coefficient for a range of angles of attack are stored in a data table. This table is generated during a pre-processing phase, where the pressure coefficients are calculated under controlled conditions for various angles of attack, reflecting how the surface interacts with the airflow under different orientations. These pre-computed values provide a quick reference during the simulation, allowing rapid retrieval of the pressure coefficient corresponding to the current angle of attack without the need for complex real-time calculations.

In some implementations, for angles of attack that fall between the pre-computed values, interpolation techniques may be utilized. Interpolation is a mathematical method used to estimate unknown values by using the known values in the surrounding range. In this context, when the angle of attack during the simulation does not exactly match one of the pre-computed values in the lookup table, the pre-computed values stored in the lookup table corresponding to the immediately lower and immediately higher angle of attack are obtained and an average (or other intermediate value) of the values may be used to determine the pressure coefficient.

In some implementations, evaluating the aerodynamic force model includes utilizing a machine learning model pre-trained on real-world aerodynamic data to predict at least the pressure coefficient for a given angle of attack. The pressure coefficient is an important parameter in the aerodynamic force model, representing the pressure distribution on the surface of a geometric assembly relative to the surrounding air pressure. It varies with the angle of attack, which is the angle between the oncoming airflow and a specific reference line on the surface, such as the chord line of an airfoil.

In some implementations, the machine learning model is trained using a dataset composed of aerodynamic measurements and simulations from real-world scenarios. This dataset includes a wide range of angles of attack, flow conditions, and surface geometries, providing a comprehensive dataset for the machine learning model to be trained on the complex relationships between these variables and the resulting pressure coefficients.

The training process includes feeding this data to the machine learning model (ML model) and adjusting its internal parameters (e.g., node weights for one or more layers of a neural network of the ML model) to minimize the error between its predictions and the actual measured values. Through this process, the machine learning model is trained to generalize from the training data, enabling it to predict pressure coefficients for new, unseen angles of attack with a high degree of accuracy.

In some implementations, during the real-time simulation, the trained machine learning model is deployed to predict the pressure coefficient based on the current angle of attack and other relevant aerodynamic conditions. When the aerodynamic force model for a geometric assembly is evaluated, the current angle of attack is provided as input to the trained machine learning model and a predicted pressure coefficient is obtained as output of the trained ML model, which is used in the subsequent force calculations. Block 206 may be followed by block 208.

At block 208, the aerodynamic force models are integrated, i.e., combined, into a broader physics simulation to refine the motion data of the mechanism. The aerodynamic forces calculated at block 206—such as, e.g., lift, drag, and other pressure-related forces—are combined with other forces, such as, e.g., gravity, friction, and inertial effects, to determine the mechanism's updated state.

In some implementations, the physics simulation serves as the computational framework where the behavior of the mechanism is dynamically modeled based on the interaction of various forces. In some implementations, this simulation is governed by the principles of Newtonian mechanics, where the net force acting on each geometric assembly results in changes to its velocity and position over time. Integrating the aerodynamic force models into the physics simulation includes applying the aerodynamic forces to each geometric assembly within the mechanism, modifying its translational and rotational velocities as dictated by the laws of motion. For example, an increase in aerodynamic drag force would reduce the forward velocity of a vehicle, while lift forces could alter the altitude of an aircraft within the simulation.

The refined motion data generated from this integration reflects the new velocities and positions of the geometric assemblies after accounting for the aerodynamic forces. This updated motion data is then used to update the simulation, allowing modeling the mechanism's behavior in real-time (e.g., within a short time window such as that a user perceives the mechanism as moving naturally, with no jitter, lag, or other simulation artifacts). In some implementations, the refinement process may be iterative, with repeat calculation and application of the aerodynamic forces in multiple simulation steps to adjust the motion of the mechanism incrementally.

In some implementations, integration of the aerodynamic force models into the physics simulation allows for complex interactions between different forces and assemblies within the mechanism. For example, in a multi-component system like an aircraft, the aerodynamic forces acting on the wings, fuselage, and tail are each computed separately and then integrated to determine the overall motion of the aircraft. The interaction between these forces can lead to nuanced behaviors such as, e.g., yaw, pitch, and roll, which can be used for flight dynamics in the virtual experience.

In some implementations, integrating the aerodynamic force models into the physics simulation includes utilizing an integrator adapted to apply the influence of the aerodynamic forces. This integrator enables accurate representation of the complexities introduced by aerodynamic forces, such as non-linearities and variable pressure distributions, which are characteristic of such simulations.

In some implementations, the integrator operates by incorporating the aerodynamic forces into the equations of motion governing each geometric assembly. These forces, which can include components such as, e.g., lift, drag, and pressure-induced effects, are integrated into the system's dynamics using numerical methods that maintain the stability and accuracy of the simulation.

In some implementations, the integrator incorporates both the translational and rotational dynamics of the assemblies, applying the aerodynamic forces in a way that updates the velocity, orientation, and position of each assembly according to the principles of Newtonian mechanics. In some implementations, the integrator is utilized to enable time-stepping within the physics simulation. Aerodynamic forces can vary significantly depending on factors such as, e.g., speed, angle of attack, and interactions with other assemblies, leading to potential instability. In various implementations, the integrator applies appropriate numerical techniques, such as, for example, adaptive time-stepping or semi-implicit methods, to ensure that the simulation remains stable even under varying aerodynamic conditions.

In some implementations, integrating the aerodynamic force models into the physics simulation includes utilizing an integrator that is an explicit integrator with adaptive time steps based on the magnitude of the evaluated aerodynamic forces. An explicit integrator is a numerical method used to solve differential equations, where the next state of the system is computed directly from the current state and the evaluated forces. In this context, the explicit integrator is designed specifically to address the aerodynamic forces acting on the geometric assemblies within the simulation, such that these forces are integrated into the overall motion of the mechanism.

In some implementations, the explicit integrator employed includes the use of adaptive time steps, which are adjusted based on the magnitude of the aerodynamic forces being evaluated. Adaptive time-stepping is a technique where the duration of each simulation step is dynamically altered according to the changing conditions within the simulation. When the aerodynamic forces acting on the mechanism are large or rapidly changing, the integrator reduces the time step to ensure that the forces are applied with greater precision (with higher number of time steps within a fixed time period), preventing numerical instability or inaccuracies. Conversely, when the forces are smaller or more stable, the time step can be increased (fewer time steps within a fixed time period), reducing the computational cost while maintaining accuracy. In some implementations, this explicit integrator is integrated into the physics simulation engine, where the state of the mechanism is continually updated based on the computed aerodynamic forces.

In some implementations, integrating the aerodynamic force models into the real-time physics simulation includes utilizing an integrator that is an implicit integrator formulated to mitigate one or more non-linearities introduced by the aerodynamic force model. Unlike explicit integrators, which calculate the next state of the mechanism directly from the current state and forces, implicit integrators solve a set of equations that account for the current state and the forces at the next time step. This may be adapted to mitigating the non-linearities that often arise in aerodynamic force models, such as those caused by, for example, complex pressure distributions, variable flow conditions, and interactions between different components of the mechanism. In some implementations, the implicit integrator mitigates these non-linearities by iteratively solving the equations governing the dynamics, taking into account the non-linear relationships between forces, velocities, and positions.

In some implementations, the real-time physics simulation is a physics simulation engine within a video game or virtual experience, and the mechanism represents an object or character within a virtual space of the video game/virtual experience. The physics simulation engine is responsible for calculating the physical interactions and behaviors of objects, characters, and other entities within the virtual experience of the game. It applies the principles of physics, such as force, motion, collision, and aerodynamics, to create a realistic and interactive experience for the player. The engine continually updates the state of the virtual world in response to player actions and environmental factors, ensuring that the simulation remains consistent with real-world physical laws.

Within this context, the mechanism being simulated may represent an object or character within the game's virtual space. In various implementations, this mechanism could take various forms, depending on the genre and setting. For example, in a racing game, the mechanism might be a vehicle navigating a track, with the physics engine simulating the aerodynamic forces acting on the car as it accelerates, turns, and interacts with the terrain. In an action-adventure game, the mechanism may be a character (avatar), with the engine simulating the physical forces involved in the character's movements, such as running, jumping, or interacting with objects in the environment. The integration of the aerodynamic force model into the physics simulation engine allows simulation of realistic aerodynamic effects on the mechanism as it moves through the virtual space. The aerodynamic force model enables calculation of the forces acting on the object or character based on its speed, orientation, and interactions with the virtual experience, such as wind or other fluid flows. These forces are then incorporated into the overall physics simulation, influencing the mechanism's motion and behavior in real-time. For example, the simulation may include determining how wind resistance affects the speed of a car or how air currents influence the trajectory of a character's jump.

In some implementations, block 202 may be performed by one or more server devices, blocks 204-206 may be performed by different client devices for different assemblies, and block 208 may be performed by one or more server devices. In other implementations, one or more of blocks 202-208 may be performed by one or more service devices. In other implementations, one or more of blocks 202-208 may be performed by one or more client devices. Many other such configurations may be feasible.

### Triangle Occlusion on an Aircraft Mesh

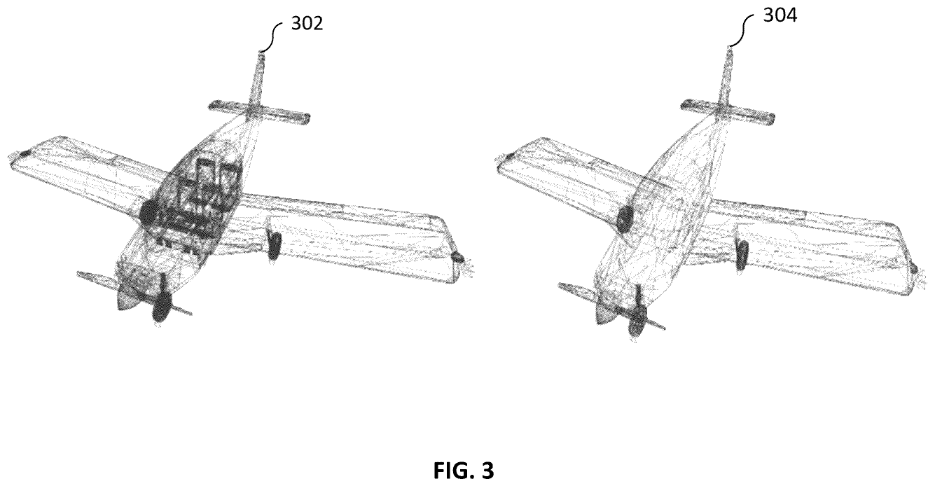

FIG. 3 is a diagram illustrating an example implementation of a triangle occlusion algorithm on an aircraft mesh, in accordance with some implementations. This diagram illustrates the process of evaluating aerodynamic forces on a rigid body by utilizing a method for triangle occlusion within the surface mesh.

In this example, mesh 302, depicted on the left, is an original mesh with 23,046 triangles, while mesh 304, depicted on the right, is an aerodynamic mesh with 9,244 triangles. The aerodynamic mesh is computed from the input surface definition, and the 9,244 triangles have exposed surfaces which were identified at block 204 of FIG. 2. The rigid body, represented by a 3D wireframe model of an aircraft, is composed of multiple geometric assemblies, each defined by its own surface mesh. These individual surface meshes are combined into a single triangulated mesh for the entire rigid body.

An asynchronous process is utilized for computing triangle occlusion. Triangle occlusion refers to the identification and removal of surface mesh triangles that are completely (or in some implementations, partially) occluded, such that they are not directly exposed to the airflow due to their position relative to other parts of the rigid body. In this process, triangles that are completely occluded are removed from the aerodynamic force calculations, as these triangles do not contribute to the forces acting on the body. For triangles that are only partially occluded, their weight in the aerodynamic force model is adjusted. The adjustment is based on the degree of occlusion of each triangle, which determines how much of the triangle is exposed to the airflow and thus how much it contributes to the overall aerodynamic forces.

Until the triangle occlusion process is complete, the unprocessed mesh can be used for initial force evaluations. In some implementations, this enables the simulation to proceed without delay while a computationally cheaper occlusion-adjusted aerodynamic force model is being evaluated. Once the triangle occlusion process is finished, the system replaces the initial force calculations with the refined results from the occluded mesh.

### Aerodynamic Force Evaluation on Mesh Triangles

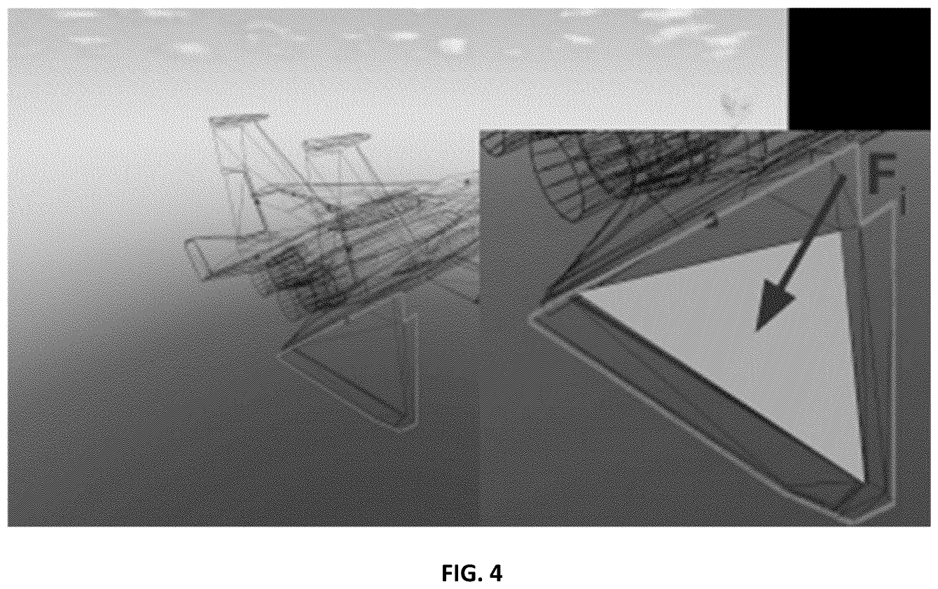

FIG. 4 is a diagram illustrating an example of aerodynamic force evaluation on each triangle in a mesh, in accordance with some implementations. The diagram illustrates aerodynamic force evaluation on each individual triangle within a mesh, as applied to a dynamic mechanism moving through a virtual space. In the example, this process involves approximating the effects of aerodynamic forces by solving complex, nonlinear systems of equations. The aerodynamic force model used for this purpose is a phenomenological approach that estimates the pressure on the surface of a body in motion relative to the surrounding air. Each triangle in the surface mesh is independently factored in, taking into account the body's linear and rotational motion.

The aerodynamic force on a single triangle is calculated using the formula:

$${F}_{i} = q A {C}_{p} ( \cdot ) {n}_{i}$$

The formula on the right side of the equation links the aerodynamic force on a triangle, Fᵢ, model to a standard representation involving dynamic pressure and the coefficient of pressure Cₚ. Here, qi denotes the dynamic pressure at the triangle's location, and Cₚ(rᵢ) is the pressure coefficient at the triangle's centroid rᵢ as a function of the velocity and normal of the centroid. This formulation allows the system to compute the aerodynamic forces by considering both the local velocity and the orientation of each triangle relative to the airflow. In some implementations, the Cₚ model switches between a simple linear function for bluff bodies and a more complex form interpolating simulation data for lifting surfaces.

The image illustrated in FIG. 4 visually represents the aerodynamic force evaluation process on individual triangles within the surface mesh of a dynamic mechanism, such as an aircraft. The left side of the figure shows the wireframe model of the aircraft, while the right side provides a close-up view of a single triangle on the surface mesh where the aerodynamic force Fᵢ is being calculated. In the close-up view, the force Fᵢ is illustrated as a vector acting on the triangle, which is one of many that constitute the surface mesh of the aircraft. The aerodynamic force on this triangle is determined using the formula described above. This process is performed independently for each triangle in the mesh, allowing the system to capture the detailed and complex interactions between the aircraft's surface and the air.

### Aerodynamic Force Evaluation

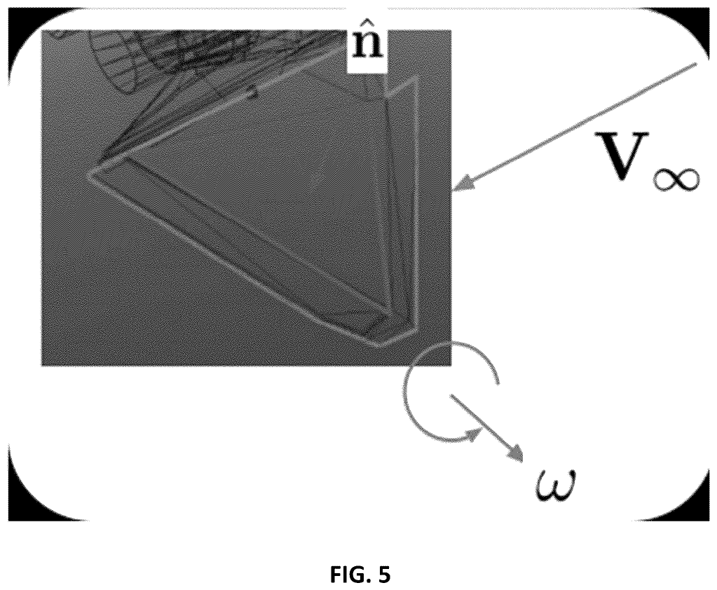

FIG. 5 is a diagram illustrating an example of an aerodynamic force evaluation, in accordance with some implementations. The diagram illustrates the process of evaluating aerodynamic forces on an individual triangle within a surface mesh, in accordance with some implementations. The figure focuses on the relationship between the force acting on the triangle and several key factors: the air density ρ, the linear velocity V_{∞}, the angular velocity ω, the surface normal \hat{n}, and the area of the triangle A, including its occlusion weight.

The left side of the figure shows a close-up of a single triangle within the aircraft's mesh, emphasizing how the aerodynamic force is influenced by the triangle's orientation and exposure to the airflow. The triangle is part of a larger geometric assembly, and the force calculation is sensitive to both the linear and angular velocities of the entire assembly. The linear velocity V_{∞} represents the speed and direction of the assembly moving through the air, while the angular velocity ω captures the rotational motion of the assembly, which affects how various parts of the surface are oriented relative to the oncoming flow. The surface normal \hat{n} defines the direction in which the pressure acts. The force on each triangle is computed as a function of this normal vector, the area of the triangle A, and the occlusion weight C, which adjusts the force based on how much of the triangle is exposed to the airflow versus being occluded by other parts of the assembly. The combination of these factors enables precise calculation of the aerodynamic force on the triangle.

Decomposition of Mechanism into Assemblies

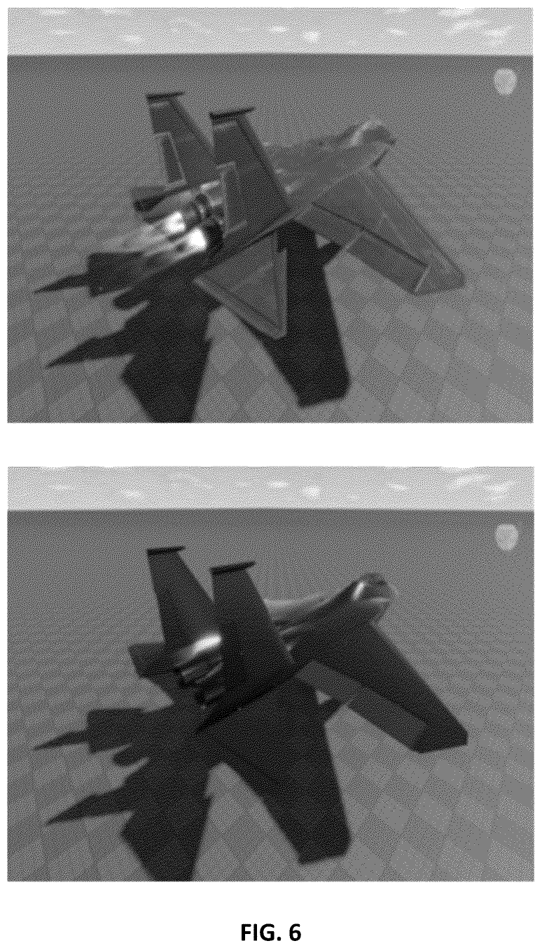

FIG. 6 is a diagram illustrating an example of mechanisms that are decomposed into assemblies whose geometry is fixed, in accordance with some implementations. The diagram illustrates an example of a complex mechanism that has been decomposed into multiple assemblies, each with its own static geometry, in accordance with some implementations. The diagram depicts an aircraft model where parts such as wings and their control surfaces can move relative to one another. In the physics simulation, a rigid-body dynamics solver is used to connect these moving parts through constraints, allowing forces to be transmitted between the bodies. This setup enables accurate simulation of interactions between various parts of the mechanism.

In some implementations, each mechanism is divided into geometric assemblies, where each assembly consists of geometry that remains static, i.e., the assembly is treated as a single, rigid, triangulated mesh without moving parts. These assemblies may contain multiple bodies, each with its own triangulation. When the assembly is first simulated, the constituent bodies are combined into a single mesh. This combined mesh undergoes preprocessing using a geometry preprocessor before the aerodynamic force model is applied. The force model is then evaluated individually for each assembly, and the resulting forces are incorporated into a rigid body dynamics simulation of the entire mechanism.

In some implementations, the process of evaluating forces on the assemblies includes several stages. Initially, before the mesh occlusion process is complete, the raw, original mesh is used to estimate aerodynamic effects. Once the occlusion is processed and an aerodynamic mesh (with fewer triangles, by including only those triangles that are exposed) is available, the force model transitions to use this refined mesh for further evaluations. For larger meshes, which exceed a predetermined size (such as, for example, 40 triangles), interpolation techniques may be used to evaluate the aerodynamic force model to save computational costs. This interpolation is computed asynchronously from the aerodynamic mesh.

In some implementations, the evaluation of forces, torques, and Jacobian matrices involves a spherical harmonic interpolator. This interpolator allows for constant-time force evaluations regardless of the original geometry's size and complexity, leading to efficiency even on devices with limited computational resources. In some implementations, the use of mathematical optimizations further reduces memory usage and execution time, ensuring that the system can model numerous aerodynamic bodies in real-time. In some implementations, constant-time force evaluation is provided by a fixed-size, reduced set of quadrature points. In some implementations, this reduced set of surface quadrature points is computed using an optimization procedure.

### Computing Device

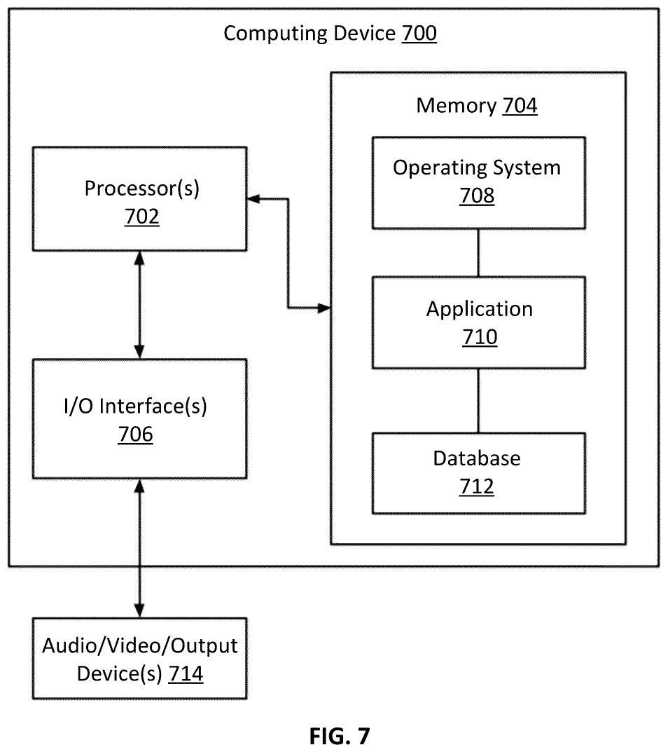

FIG. 7 is a block diagram of an example computing device 700 which may be used to implement one or more techniques described herein. In one example, device 700 may be used to implement a computer device (e.g., 102 and/or 110 of FIG. 1), and perform appropriate method implementations described herein. Computing device 700 can be any suitable computer system, server, or other electronic or hardware device. For example, the computing device 700 can be a mainframe computer, desktop computer, workstation, portable computer, or electronic device (portable device, mobile device, cell phone, smartphone, tablet computer, television, TV set top box, personal digital assistant (PDA), media player, game device, wearable device, etc.). In some implementations, device 700 includes a processor 702, a memory 704, input/output (I/O) interface 706, and audio/video input/output devices 714.

Processor 702 can be one or more processors and/or processing circuits to execute program code and control basic operations of the device 700. A “processor” includes any suitable hardware and/or software system, mechanism or component that processes data, signals or other information. A processor may include a system with a general-purpose central processing unit (CPU), multiple processing units, dedicated circuitry for achieving functionality, or other systems. Processing need not be limited to a particular geographic location, or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory.

Memory 704 is provided in device 700 for access by the processor 702, and may be any suitable computer-readable or processor-readable storage medium, e.g., random access memory (RAM), read-only memory (ROM), Electrical Erasable Read-only Memory (EEPROM), Flash memory, etc., suitable for storing instructions for execution by the processor, and located separate from processor 702 and/or integrated therewith. Memory 704 can store software operating on the server device 700 by the processor 702, including an operating system 708, one or more applications 710, and a database 712 that may store data used by the components of device 700.

Database 712 may store one or more mechanisms, comprising a plurality of geometric assemblies that are physically coupled and can be simulated in a virtual space. In some implementations, database 712 may store multiple mechanisms in association with a virtual experience, e.g., mechanisms an aircraft, clouds, trees, balloons, and other objects in a “flying simulator” virtual experience; one or more cars, bikes, trucks, and other objects in a “car racing” experience; and so on. In some implementations, database 712 may also store other data, as described with reference to FIG. 2, e.g., a lookup table. In some implementations, applications 710 can include instructions that enable processor 702 to perform the functions (or control the functions of) described herein, e.g., some or all of the methods described with respect to FIG. 2.

For example, applications 710 can include a module that implements one or more machine learning models used in techniques described herein, e.g., learned diffusion layers such as DiffusionNet, multi-layer perceptron, PointNet, or transformer self-attention layers. Applications 710 can include one or both of the loss functions of FIG. 3, that is, a) a squared L2-difference in the size similarity between the prediction and the ground truth, and/or b) a squared L2-difference in the directional similarity between the prediction and the ground truth. Database 712 (and/or other connected storage) can store various data used in described techniques, including input meshes of an avatar, quad meshes, output retopologized meshes, features 306, barycenters, local coordinate frames, etc.

Elements of software in memory 704 can alternatively be stored on any other suitable storage location or computer-readable medium. In addition, memory 704 (and/or other connected storage device(s)) can store instructions and data used in the features described herein. Memory 704 and any other type of storage (magnetic disk, optical disk, magnetic tape, or other tangible media) can be considered “storage” or “storage devices.”

I/O interface 706 can provide functions to enable interfacing the server device 700 with other systems and devices. For example, network communication devices, storage devices (e.g., memory and/or data store 120), and input/output devices can communicate via interface 706. In some implementations, the I/O interface can connect to interface devices including input devices (keyboard, pointing device, touchscreen, microphone, camera, scanner, etc.) and/or output devices (display device, speaker devices, printer, motor, etc.).

The audio/video input/output devices 714 can a variety of devices including a user input device (e.g., a mouse, etc.) that can be used to receive user input, audio output devices (e.g., speakers), and a display device (e.g., screen, monitor, etc.) and/or a combined input and display device, which can be used to provide graphical and/or visual output.

For ease of illustration, FIG. 7 shows one block for each of processor 702, memory 704, I/O interface 706, and software blocks of operating system 708 and virtual experience application 710. These blocks may represent one or more processors or processing circuitries, operating systems, memories, I/O interfaces, applications, and/or software engines. In other implementations, device 700 may not have all of the components shown and/or may have other elements including other types of elements instead of, or in addition to, those shown herein. While the online virtual experience server 102 is described as performing operations as described in some implementations herein, any suitable component or combination of components of online virtual experience server 102, client device 110, or similar system, or any suitable processor or processors associated with such a system, may perform the operations described.

Device 700 can be a server device or client device. Example client devices or user devices can be computer devices including some similar components as the device 700, e.g., processor(s) 702, memory 704, and I/O interface 706. An operating system, software and applications suitable for the client device can be provided in memory and used by the processor. The I/O interface for a client device can be connected to network communication devices, as well as to input and output devices, e.g., a microphone for capturing sound, a camera for capturing images or video, a mouse for capturing user input, a gesture device for recognizing a user gesture, a touchscreen to detect user input, audio speaker devices for outputting sound, a display device for outputting images or video, or other output devices. A display device within the audio/video input/output devices 714, for example, can be connected to (or included in) the device 700 to display images pre- and post-processing as described herein, where such display device can include any suitable display device, e.g., an LCD, LED, or plasma display screen, CRT, television, monitor, touchscreen, 3-D display screen, projector, or other visual display device. Some implementations can provide an audio output device, e.g., voice output or synthesis that speaks text.

One or more methods described herein (e.g., method 200 and other described techniques) can be implemented by computer program instructions or code, which can be executed on a computer. For example, the code can be implemented by one or more digital processors (e.g., microprocessors or other processing circuitry), and can be stored on a computer program product including a non-transitory computer readable medium (e.g., storage medium), e.g., a magnetic, optical, electromagnetic, or semiconductor storage medium, including semiconductor or solid state memory, magnetic tape, a removable computer diskette, a random access memory (RAM), a read-only memory (ROM), flash memory, a rigid magnetic disk, an optical disk, a solid-state memory drive, etc. The program instructions can also be contained in, and provided as, an electronic signal, for example in the form of software as a service (SaaS) delivered from a server (e.g., a distributed system and/or a cloud computing system). Alternatively, one or more methods can be implemented in hardware (logic gates, etc.), or in a combination of hardware and software. Example hardware can be programmable processors (e.g., Field-Programmable Gate Array (FPGA), Complex Programmable Logic Device), general purpose processors, graphics processors, Application Specific Integrated Circuits (ASICs), and the like. One or more methods can be performed as part of or component of an application running on the system, or as an application or software running in conjunction with other applications and operating systems.

One or more methods described herein can be run in a standalone program that can be run on any type of computing device, a program run on a web browser, a mobile application (“app”) run on a mobile computing device (e.g., cell phone, smart phone, tablet computer, wearable device (wristwatch, armband, jewelry, headwear, goggles, glasses, etc.), laptop computer, etc.). In one example, a client/server architecture can be used, e.g., a mobile computing device (as a client device) sends user input data to a server device and receives from the server the final output data for output (e.g., for display). In another example, all computations can be performed within the mobile app (and/or other apps) on the mobile computing device. In another example, computations can be split between the mobile computing device and one or more server devices.

Although the description has been described with respect to particular implementations thereof, these particular implementations are merely illustrative, and not restrictive. Concepts illustrated in the examples may be applied to other examples and implementations.

The functional blocks, operations, features, methods, devices, and systems described in the present disclosure may be integrated or divided into different combinations of systems, devices, and functional blocks as would be known to those skilled in the art. Any suitable programming language and programming techniques may be used to implement the routines of particular implementations. Different programming techniques may be employed, e.g., procedural or object-oriented. The routines may execute on a single processing device or multiple processors. Although the steps, blocks, operations, or computations may be presented in a specific order, the order may be changed in different particular implementations. In some implementations, multiple steps or operations shown as sequential in this specification may be performed at the same time.

1. A computer-implemented method comprising:
receiving a description of a mechanism comprising a plurality of physically coupled geometric assemblies within a virtual experience, each geometric assembly defining a surface mesh, the description comprising motion data of the mechanism;
for each geometric assembly,
identifying exposed surface areas of the surface mesh; and
evaluating an aerodynamic force model based on the exposed surface areas and the motion data of the mechanism, wherein the aerodynamic force model comprises a pressure coefficient that varies based on an angle of attack and based on windward and leeward facing surfaces; and
integrating the aerodynamic force models into a physics simulation to refine the motion data of the mechanism in the virtual experience.

2. The computer-implemented method of claim 1, wherein the aerodynamic force model further for each geometric assembly comprises a pressure model based on pressure on the exposed surface areas of the geometric assembly in relative motion to air simulated within the virtual experience.

3. The computer-implemented method of claim 1, wherein identifying the exposed surface areas of the surface meshes comprises utilizing low discrepancy sampling and ray casting.

4. The computer-implemented method of claim 1, wherein integrating the aerodynamic force models into the physics simulation comprises utilizing an integrator adapted to apply influence of aerodynamic forces of the aerodynamic force model.

5. The computer-implemented method of claim 1, wherein evaluating the aerodynamic force model comprises utilizing high-order quadrature to approximate a force integral on the exposed surface areas.

6. The computer-implemented method of claim 5, wherein the high-order quadrature utilizes a predetermined number of quadrature points determined based on a trade-off between accuracy and computational cost.

7. The computer-implemented method of claim 1, wherein evaluating the aerodynamic force model comprises utilizing a pre-computed spherical harmonic interpolator for the aerodynamic force model.

8. The computer-implemented method of claim 7, wherein evaluating the aerodynamic force model further comprises evaluating derivatives of the aerodynamic force model with respect to linear and angular velocity unit vectors directly from the pre-computed spherical harmonic interpolator.

9. The computer-implemented method of claim 1, wherein evaluating the aerodynamic force model comprises:
determining that the evaluation is being performed with respect to the surface mesh defined by the geometric assembly that is above a specified threshold; and
generating a set of optimized quadrature points and weights for the surface mesh using an optimization process.

10. The computer-implemented method of claim 9, wherein the set of optimized quadrature points and weights is used for real-time force evaluation on the surface mesh.

11. The computer-implemented method of claim 1, wherein evaluating the aerodynamic force model comprises utilizing a mesh simplification technique to reduce a number of triangles in the surface mesh defined by the geometric assembly prior to occlusion detection and exposed surface area calculation.

12. The computer-implemented method of claim 1, wherein evaluating the aerodynamic force model comprises pre-computing coefficients for Fₜ and F_{c} terms of the aerodynamic force model during a geometric assembly pre-processing stage.

13. A system comprising:
one or more processors; and
memory coupled to the one or more processors storing instructions that, when executed by the one or more processors, cause the system to perform operations comprising:
receiving a description of a mechanism comprising a plurality of physically coupled geometric assemblies within a virtual experience, each geometric assembly defining a surface mesh, the description comprising motion data of the mechanism;
for each geometric assembly,
identifying exposed surface areas of the surface mesh; and
evaluating an aerodynamic force model based on the exposed surface areas and the motion data of the mechanism, wherein the aerodynamic force model comprises a pressure coefficient that varies based on an angle of attack and based on windward and leeward facing surfaces; and
integrating the aerodynamic force models into a physics simulation to refine the motion data of the mechanism.

14. The system of claim 13, wherein integrating the aerodynamic force models into the physics simulation comprises utilizing an integrator that is an explicit integrator with adaptive time steps based on a magnitude of the evaluated aerodynamic forces.

15. The system of claim 13, wherein integrating the aerodynamic force models into the physics simulation comprises utilizing an integrator that is an implicit integrator formulated to mitigate one or more non-linearities introduced by the aerodynamic force model.

16. The system of claim 13, wherein evaluating the aerodynamic force model comprises:
identifying non-exposed surface areas of the surface meshes; and
excluding the non-exposed surface areas of the surface meshes from an exposed surface area calculation.

17. The system of claim 13, wherein evaluating the aerodynamic force model comprises utilizing a table lookup for the pressure coefficient within the force model, wherein a table stores pre-computed pressure coefficient values for a range of angles of attack and incorporates interpolation for intermediate values.

18. The system of claim 13, wherein evaluating the aerodynamic force model comprises utilizing a machine learning model pre-trained on real-world aerodynamic data to predict at least the pressure coefficient for a given angle of attack.

19. The system of claim 13, wherein the physics simulation is a physics simulation engine within a video game, and the mechanism represents an object within a virtual space of the video game.

20. A non-transitory computer-readable medium with instructions stored thereon that, when executed by a processor, cause the processor to perform operations comprising:
receiving a description of a mechanism comprising a plurality of physically coupled geometric assemblies within a virtual experience, each geometric assembly defining a surface mesh, the description further comprising motion data of the mechanism;
for each geometric assembly,
identifying exposed surface areas of the surface mesh; and
evaluating an aerodynamic force model based on the exposed surface areas and the motion data of the mechanism, wherein the aerodynamic force model comprises a pressure coefficient that varies based on an angle of attack and based on windward and leeward facing surfaces; and
integrating the aerodynamic force models into a physics simulation to refine the motion data of the mechanism.
